(19) United States
(12) Patent Application Publication
(10) Pub. No.: US 2014/0261169 A1
(43) Pub. Date: Sep. 18, 2014

(54) SPUTTERING APPARATUS FOR REDUCING SUBSTRATE DAMAGE AND METHOD FOR APPLYING THE SAME

(71) Applicant: EverDisplay Optronics (Shanghai) Limited, Shanghai (CN)

(72) Inventor: PeiMing Chu, Shanghai (CN)

(73) Assignee: EverDisplay Optronics (Shanghai) Limited, Shanghai (CN)

(21) Appl. No.: 14/150,487

(22) Filed: Jan. 8, 2014

(30) Foreign Application Priority Data
Mar. 15, 2013 (CN) 201310084848.2

(51) Int. Cl. C23C 14/34

(52) U.S. Cl. CPC C23C 14/34
USPC 118/620

(57) ABSTRACT

The present disclosure discloses a sputtering apparatus for reducing the damage to the base board caused by ITO sputtering and the method thereof. The sputtering chamber of the sputtering apparatus includes a base board connection structure for setting a base board and a target connection structure for setting a target. The target connection structure makes the target locate on the side of the base board connection structure. The target connection structure forms a precalculated angle with the base board. There is a space between the target and the base board. The target connection structure includes a negative potential generator for generating negative potential. The negative potential is applied to the target which is connected to the target connection structure. The sputtering chamber of the apparatus further includes an anode plate which is in parallel with the target material.

### CROSS-REFERENCE TO RELATED APPLICATIONS

The present application claims priority to and the benefit of Chinese Patent Application No. CN 201310084848.2, filed on Mar. 15, 2013, the entire content of which is incorporated herein by reference.

### BACKGROUND OF THE INVENTION

1. Field of the Invention

The present disclosure relates to the technology of a sputtering apparatus, more specifically, to a sputtering apparatus for reducing substrate damage caused by ITO sputtering and a method of applying the same.

2. Description of the Related Art

ITO is a good transparent conductive material. It is generally used for forming the transparency electrode. However, in the application of the AMOLED display, the ITO needs to be deposited on the surface of the OLED organic material in some device structures. In this process, the surface of OLED organic material used as the substrate is likely to be damaged by the bump of the energetic particles generated in the sputtering process, thereby the performance thereof is influenced. Furthermore, in the ITO sputtering process, the UV-light is often generated with the process of the plasma discharge in ITO sputtering, which causes the adverse effects to the performance of the organic material.

In one related art, a sputtering method concerns depositing a material onto an organic material, wherein the discharge gas in the sputtering operation has a light emission spectrum with an amount of energy lower than that of argon.

In another related art, a mask for protecting the substrates edges being sputtered from the sputtering material includes grooves which loosely receive the substrates. The width of the grooves exceeds the width of the substrates by a first dimension and the depth of the grooves above the substrate exceeds the thickness of the substrates by a second dimension. The ratio of the first dimension to the second dimension is at least 5. Consequently, the prior art did not solve the problem of damaging the substrate in ITO sputtering operation.

### SUMMARY OF THE INVENTION

An aspect of an embodiment of the present disclosure is directed toward a sputtering apparatus for reducing the substrate damage caused by ITO sputtering, which is capable of avoiding the damage to the substrate in ITO sputtering operation.

Another aspect of an embodiment of the present disclosure is directed toward a method of applying the sputtering apparatus for reducing substrate damage caused by ITO sputtering.

An embodiment of the present disclosure provides a sputtering apparatus for reducing substrate damage caused by ITO sputtering The apparatus comprises a chamber having a base board connection structure for setting a base board; and a sputtering generating element for generating sputtering particles at a side of the said base board connection structure; and a space defined between the base board connected to the said base board connection structure and the said sputtering generating element; wherein the sputtering plane of the said sputtering generating element is not in parallel but has a preconfigured angle relative to the surface of the substrate connected to the said substrate connection structure.

The said sputtering generating element comprises a target, an anode plate in parallel with the said target and a negative potential generator; the said anode plate is connected to the positive potential; a negative potential is generated and applied to the said target by the said negative potential generator to generate plasma between the said anode plate and the said target for bombarding the said target. The said target is set in the said chamber by a target connection structure. A plurality of the said sputtering generating elements is set at the side of the said substrate in parallel. The anode plate or the target of two adjacent sputtering generating elements are opposite to etch other. A movement device is also disclosed to connect to the said base board connection structure to move the said base board connection structure. The height of the target is less than or equal to that of the anode plate. The height of the target is less than the length of the base board connected to the said base board connection structure. The said preconfigured angle is 90°.

Another embodiment of the present disclosure provides a method of applying the sputtering apparatus for reducing substrate damage caused by ITO sputtering. The method comprises the steps of: preparing a target at a side of a base board with a preconfigured angle; the target is not in parallel with the base board; sputtering particles to the target; and forming a thin-film on the said base board with the sputtering particles.

The reactant gas for generating the plasma is argon gas, or the mixture of argon gas and oxygen gas, or the mixture of argon gas and water vapor. The reactant between the said anode plate and the said target is ionized to form the said plasma by applying the positive potential to an anode plate set in parallel with the said target and by applying the negative potential to the said target. A plurality of sputtering generating elements is mainly formed by the said anode plate and the said target; a plurality of the sputtering generating elements is set at the side of the base board connection structure in parallel. The anode plate or the target of two adjacent sputtering generating elements is opposite to etch other. The said base board is moved by a moving device during the process of the forming step. The said target is preconfigured to have an angle, preferably, 90°.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a structure diagram of the sputtering apparatus in the embodiment of the present disclosure which reduces substrate damage caused by ITO sputtering;

FIG. 2 shows a structure diagram of the sputtering apparatus in an embodiment of the present disclosure which reduces substrate damage caused by ITO sputtering;

FIG. 3 shows a diagram of the method in an embodiment of the present disclosure, which reduces substrate damage caused by ITO sputtering;

FIG. 4 shows a flow chart of the method in the embodiment of the present disclosure which reduces substrate damage caused by ITO sputtering.

### DETAILED DESCRIPTIONS

Hereinafter, certain exemplary embodiments according to the present disclosure will be described with reference to the accompanying drawings.

The present disclosure will be further illustrated in combination with the following figures and embodiments, but it should not be deemed as limitation of the present disclosure.

FIG. 1 shows a structure diagram of the sputtering apparatus in the embodiment of the present disclosure, which reduces substrate damage caused by ITO sputtering. The sputtering chamber of the sputtering apparatus comprises a Base Board Connection Structure 4 for setting the base board and a Target Connection Structure 3 for setting the target. The target connected to the target connection structure is located at the side of Base Board Connection Structure 4 by Target Connection Structure 3. The target may be located above or below the base board. The target is not in parallel with the base board which is connected to Base Board Connection Structure 4, and may be vertical to the base board. A space is defined between the target and the base board by Target Connection Structure 3. Target Connection Structure 3 comprises a negative potential generator (not shown in the figure). The negative potential generator generates a negative potential. The negative potential is applied to the target which connects the target connection structure by the negative potential generator.

The sputtering chamber of the sputtering apparatus further comprises an Anode Plate 1 in parallel with Target Connection Structure 3. The anode plate 1 is used to form an electrical field with the target connected to the target connection structure. The electrical field is located between Anode Plate 1 and the target connected to the target connection structure. Hence, Plasma 2 is generated when the reactant gas is introduced into the sputtering chamber. Base Board Connection Structure 4 is placed at the side of the Plasma 2. Since there is no need to cover the entire area of the base board connected to the base board connection structure by Target Connection Structure 3, the area of the target can be reduced greatly. The width and height thereof can be reduced in a certain extent to ensure the generation of Plasma 2. Therefore, the cost of production is greatly reduced. Meanwhile, in order to generate Plasma 2, the distance between Anode Plate 1 and Target Connection Structure 3 is smaller than a certain default value, therefore it can not cover the whole Base Board Connection Structure 4 in length. The height of the target connected to Target Connection Structure 3 may be less than or equal to the height of Anode Plate 1. The area of the target may be less than or equal to the area of Anode Plates 1. The height of the target connected to the target connection structure can be less than the length of the base board connected to Base Board Connection Structure 4; or the area of the target may be less than that of the base board. In the embodiment, the length is directed to the horizontal direction in FIG. 1, the height is directed to the vertical direction in FIG. 1, and the width is perpendicular to the plane of the figure.

FIG. 2 shows a structure diagram of the sputtering apparatus in an embodiment of the present disclosure which reduces the damage to the substrate caused by ITO sputtering. The base board is covered just by an Anode Plate 1 and a target, so the length of the coverage is limited. At this time, a sputtering generating element can be formed by Target Connection Structure 3 and Anode Plate 1. A plurality of the sputtering generating elements is placed at the side of Base Board Connection Structure 4 in parallel. For example, it can be located above or below the base board. A plurality of the sputtering generating elements is set by the way that Anode Plate 1/Target Connection Structure 3 in a sputtering generating element is opposite to Target Connection Structure 3/Anode Plate 1 in the adjacent sputtering generating element. In the process of ITO sputtering, the base board connected to the base board connection structure can be sputter coated of a large area by the way of setting several pairs of the target and the anode plate.

FIG. 3 shows a diagram of the method in an embodiment of the present disclosure which reduces the damage to the substrate caused by ITO sputtering. Since the length of the base board covered just by an Anode Plate 1 and a target is limited, the Base Board Connection Structure 4 can be connected to a movement device (not shown in the figure). Base Board Connection Structure 4 is moved with the base board connected to Base Board Connection Structure 4 by the movement device, which dynamically forms films on the base board connected to Base Board Connection Structure 4 similar to scanning Thereby, the purpose of large area sputter coating is achieved.

FIG. 4 shows a flow diagram of the method in the embodiment of the present disclosure which reduces the damage to the substrate caused by ITO sputtering. The method for reducing the substrate damage caused by ITO sputtering, comprising the before mentioned sputtering apparatus for reducing the substrate damage caused by ITO sputtering, and specifically includes the following steps:

(a), the said target is set at a side of the said base board, such as, the upward side or the downward side. The said target connection structure also forms a precalculated angle with the base board connected to the base board connection structure, such as a vertical angle. A space is reserved between the said target and the base board. The height of the said target is smaller than the length of the said base board.

Step 1, an anode plate is set in parallel with the said target. A positive potential is applied to the said anode plate. A negative potential is applied to the said target. An electric field is formed between the said anode plate and the said target, wherein, the area of the said target is less than or equal to the area of the said anode plate.

Step 2, the reactant gas are inlet in the sputtering chamber.

Step 3, the sputter coating operation is performed on the base board by utilizing the side portion of the target.

The preset angel between the base board and the target can be 90°. The base board is coated by utilizing the side portion of the target, where the magnetic field and the electric field are weaker. As the energy of the particle here is relatively weaker, it is not easy to damage the substrate material on the base board. The area of the target is less than or equal to that of the anode plate.

In the embodiment of the invention, the reactant gas may be argon gas, the mixture of argon gas and oxygen gas or the mixture of argon gas and water vapor. Presently, the argon gas is the inert gas widely used in the industry. Since it is stable, it is suitable for the sputter coating operation of the base board. Thus, in the process of the ITO sputtering operation, the sputtering target is used as a cathode. A negative potential is applied to the target. The target is opposite to the anode plate. An electric field is formed. The argon gas is inlet in the chamber, and with the effect of the electric field, the free electrons are accelerated to ionize the argon atoms and form the glow discharge. The argon ions bump the target to generate the atoms from the target and the secondary electrons etc. Then the target atoms are deposited on the base board to form a thin film. The secondary electron mainly plays a role of maintaining the glow discharge. After being hit, the target atoms are generated with a higher speed. However, the magnetic field and electric field on the edge of the target is weaker. Thus, the momentum of the target atoms is greatly reduced, when target atoms deposited onto the base board, it will not produce a very large bombardment effect. When the base board is provided with the substrate material, the damage on the material surface will be greatly reduced, thereby the substrate or the substrate on the base board will be protected.

In the embodiment of the present disclosure, the target is set on the target connection structure. The said target connection structure and the anode plate forms a sputtering generating element. Step 2 further comprises: Step 2.1, a plurality of the sputtering generating elements is set at the side of the substrate connection structure in parallel; Step 2.2, a plurality of the sputtering generating elements is set by the way that Anode Plate 1/Target Connection Structure 3 in a sputtering generating element is opposite to Target Connection Structure 3/Anode Plate 1 in the adjacent sputtering generating element.

In the embodiment of the present disclosure, the sputter coating operation in Step 4 comprises moving the substrate in the sputtering process, such as the moving in the horizontal direction.

The method of the present disclosure can effectively reduce the damage of substrate in the process of ITO sputtering operation, and thereby improve the product yield and the device performance, and it has a wide range of applications.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A sputtering apparatus for reducing substrate damage, the sputtering apparatus comprising:
a chamber having a base board; a base board connection structure for setting the base board;
a sputtering generating element to generate sputtering particles on the base board connection structure; and
a space defined between the base board and the sputtering generating element;
wherein, the sputtering plane of the sputtering generating element is placed with a preconfigured angle relative to the surface of the substrate connected to the substrate connection structure.

2. The sputtering apparatus as disclosed in claim 1, wherein the sputtering generating element comprises a target, an anode plate in parallel with the target and a negative potential generator; the anode plate is connected to the positive potential; a negative potential is generated and applied to the target by the negative potential generator to generate plasma between the anode plate and the target for bombarding the target.

3. The sputtering apparatus as disclosed in claim 2, wherein the target is located in the chamber by a target connection structure.

4. The sputtering apparatus as disclosed in claim 1, wherein a plurality of the sputtering generating elements is on a side and parallel to the substrate.

5. The sputtering apparatus as disclosed in claim 1, wherein in a plurality of the sputtering generating elements, the anode plate or the target of two adjacent sputtering generating elements are set by the means that is opposite to etch other.

6. The sputtering apparatus as disclosed in claim 1 further comprising a movement device connected to the base board connection structure to move the base board connection structure.

7. The sputtering apparatus as disclosed in claim 2, wherein height of the target is less than or equal to that of the anode plate.

8. The sputtering apparatus as disclosed in claim 2, wherein height of the target is less than a length of the base board connected to the base board connection structure.

9. The sputtering apparatus as disclosed in claim 1, wherein the preconfigured angle is 90°.
